(19) United States
(12) Patent Application Publication
(10) Pub. No.: US 2019/0074338 A1
(43) Pub. Date: Mar. 7, 2019

(54) DISPLAY PANEL, DISPLAY APPARATUS, AND METHOD FOR PRODUCING DISPLAY PANEL

(71) Applicant: BOE Technology Group Co., Ltd., Beijing (CN)

(72) Inventor: Pengfei Gu, Beijing (CN)

(21) Appl. No.: 16/124,079

(22) Filed: Sep. 6, 2018

(30) Foreign Application Priority Data
Sep. 7, 2017 (CN) 201710803989.3

(51) Int. Cl. H01L 27/32; H01L 51/52; H01L 51/56

(52) U.S. Cl. CPC H01L 27/3246; H01L 27/326; H01L 51/56; H01L 51/5234; H01L 27/3276

(57) ABSTRACT

There is provided a display panel, display apparatus, and a method for producing a display panel. The display panel has: a substrate; a planarization layer on the substrate; a first electrode on the planarization layer; a light-emitting layer on the first electrode; a second electrode on the light-emitting layer; and an auxiliary electrode in the planarization layer, wherein the auxiliary electrode is electrically connected to the second electrode.

### CROSS-REFERENCE TO RELATED APPLICATION

This disclosure claims the priority of Chinese Patent Application No. 201710803989.3 filed on Sep. 7, 2017, which is incorporated herein in its entirety by reference.

### TECHNICAL FIELD

This disclosure relates to the technical field of display. More particularly, this disclosure relates to a display panel, display apparatus, and a method for producing a display panel.

### BACKGROUND ART

In a display panel, a transparent electrode such as a transparent cathode is needed. The transparent electrode has a relatively high requirement for the transmittance of light, so that the thickness of the transparent electrode should be as thin as possible. However, the thinner the film layer of the transparent electrode is, the higher the resistance thereof is. An excessively high resistance leads to the occurrence of IR drop over the transparent electrode, which influences the display uniformity of the entire surface. This case is particularly notable in a large-size panel.

### SUMMARY OF THE INVENTION

In one aspect of this disclosure, there is provided a display panel, comprising:
a substrate;
a planarization layer on the substrate;
a first electrode on the planarization layer;
a light-emitting layer on the first electrode;
a second electrode on the light-emitting layer; and
an auxiliary electrode, which is in the planarization layer and electrically connected to the second electrode.

According to one embodiment of this disclosure, the display panel further comprises: a pixel defining layer, which is on the planarization layer and defines a pixel area, wherein the light-emitting layer is formed in the pixel area, and wherein the auxiliary electrode is electrically connected to the second electrode via a hole located in the pixel defining layer and the planarization layer.

According to another embodiment of this disclosure, the planarization layer comprises:
a first planarization sublayer, and
a second planarization sublayer,
wherein the first planarization sublayer is on the substrate, the auxiliary electrode is on the first planarization sublayer, and the second planarization sublayer covers the auxiliary electrode and the first planarization sublayer.

According to another embodiment of this disclosure, the display panel further comprises: a pixel defining layer, which is on the second planarization sublayer and defines a pixel area, wherein the light-emitting layer is in the pixel area, and wherein the auxiliary electrode is electrically connected to the second electrode via a through hole penetrating the pixel defining layer and the second planarization sublayer.

According to another embodiment of this disclosure, a thickness of the first planarization sublayer is 0.5 μm to 1.5 μm, and a thickness of the second planarization sublayer is 0.5 μm to 1.5 μm.

According to another embodiment of this disclosure, the second planarization sublayer comprises a part covering the auxiliary electrode and a part covering and contacting the first planarization sublayer, wherein a thickness of the part covering and contacting the first planarization sublayer is equal to a sum of a thickness of the part covering the auxiliary electrode and a thickness of the auxiliary electrode.

According to another embodiment of this disclosure, a ratio D1/(D2+D3) of a thickness D1 of the auxiliary electrode to a sum of a thickness D2 of the first planarization sublayer and a thickness D3 of the part covering and contacting the first planarization sublayer is 1:10 to 1:3.

According to another embodiment of this disclosure, a thickness of the auxiliary electrode is 300 nm to 750 nm; and a sum of a thickness of the first planarization sublayer and a thickness of the part covering and contacting the first planarization sublayer is 1 μm to 3 μm.

According to another embodiment of this disclosure, a ratio of an area of the auxiliary electrode in a direction parallel to the substrate to an area of the planarization layer in a direction parallel to the substrate is 1:1.2 to 1:5.

According to another embodiment of this disclosure, the auxiliary electrode is a mesh electrode.

According to another embodiment of this disclosure, the auxiliary electrode has a multilayer structure comprising a first protective conductive layer, a conductive metal layer, and a second protective conductive layer, wherein the conductive metal layer is located between the first protective conductive layer and the second protective conductive layer, thicknesses of the first protective conductive layer and the second protective conductive layer are each independently 10 to 100 nm, and a thickness of the conductive metal layer is 300 to 500 nm.

According to another embodiment of this disclosure, the first electrode comprises AlNd or Al, the conductive metal layer comprises Cu, and the first protective conductive layer and the second protective conductive layer comprise MoNb.

According to another embodiment of this disclosure, the first electrode is an anode, and the second electrode is a cathode.

In another aspect of this disclosure, there is provided a display apparatus, comprising a display panel according to any one described above.

In yet another aspect of this disclosure, there is provided a method for producing a display panel, comprising the steps of:
forming a planarization layer on a substrate,
forming a first electrode on the planarization layer;
forming a light-emitting layer on the first electrode; and
forming a second electrode on the light-emitting layer;
wherein an auxiliary electrode is formed in the planarization layer and the auxiliary electrode is electrically connected to the second electrode.

According to another embodiment of this disclosure, the method comprises the steps of:
forming a first planarization sublayer on a substrate;
forming an auxiliary electrode on the first planarization sublayer;
forming a second planarization sublayer on the first planarization sublayer having the auxiliary electrode formed thereon;
forming a first through hole, which is in communication with the auxiliary electrode, in the second planarization sublayer;
forming a first electrode on the second planarization sublayer by using a first electrode material;
forming a pixel defining layer, which defines a pixel area, on the second planarization sublayer;
forming a second through hole, which is in communication with the first through hole, in the pixel defining layer;
forming a light-emitting layer in the pixel area; and
forming a second electrode on surfaces of the light-emitting layer and the pixel defining layer by using a second electrode material, wherein the second electrode material fills the first through hole and the second through hole, and is electrically connected to the auxiliary electrode.

According to another embodiment of this disclosure,
the display panel further comprises a passivation layer located on the substrate and under the first planarization sublayer, and a thin-film transistor located on the substrate and under the passivation layer, wherein the thin-film transistor has a drain electrode,
and the method further comprises:
forming a third through hole in the first planarization sublayer and above the drain electrode;
forming a fourth through hole in the second planarization sublayer; and
forming a fifth through hole in the passivation layer, wherein the fifth through hole and the fourth through hole are in communication with the third through hole;
wherein when forming a first electrode on the second planarization sublayer by using a first electrode material, the first electrode material fills the fourth through hole, the third through hole, and the fifth through hole, and electrically connects the first electrode to the drain electrode of the thin-film transistor.

### DESCRIPTION OF DRAWINGS

In order to illustrate the technical solutions in examples of this disclosure more clearly, figures required for describing the examples will be simply introduced below. It is apparent that the figures described below are merely exemplary examples of this disclosure, and other figures may be further obtained by those of ordinary skill in the art according to these figures without exerting inventive work.

FIG. 1 is a sectional schematic view exemplarily representing a display panel in a direction perpendicular to the substrate.

FIG. 2 is a sectional schematic view exemplarily representing another display panel in a direction perpendicular to the substrate.

FIG. 3 is a sectional schematic view exemplarily representing a display panel according to one embodiment of this disclosure in a direction perpendicular to the substrate.

FIG. 4 is a schematic plan view exemplarily representing an auxiliary electrode of a display panel according to another embodiment of this disclosure.

FIG. 5 is a sectional schematic view exemplarily representing a display panel according to another embodiment of this disclosure in a direction perpendicular to the substrate when a first planarization sublayer is formed on a passivation layer.

FIG. 6 is a sectional schematic view exemplarily representing a display panel according to another embodiment of this disclosure in a direction perpendicular to the substrate when an auxiliary electrode is formed on a first planarization sublayer and is patterned.

FIG. 7 is a sectional schematic view exemplarily representing a display panel according to another embodiment of this disclosure in a direction perpendicular to the substrate when a second planarization sublayer is formed on a first planarization sublayer and an auxiliary electrode.

FIG. 8 is a sectional schematic view exemplarily representing a display panel according to another embodiment of this disclosure in a direction perpendicular to the substrate when a through hole is formed in a passivation layer to expose a drain electrode.

FIG. 9 is a sectional schematic view exemplarily representing a display panel according to another embodiment of this disclosure in a direction perpendicular to the substrate when a first electrode is formed on a second planarization sublayer and is patterned.

FIG. 10 is a sectional schematic view exemplarily representing a display panel according to another embodiment of this disclosure in a direction perpendicular to the substrate when a pixel defining layer is formed on a second planarization sublayer.

FIG. 11 is a sectional schematic view exemplarily representing a display panel according to another embodiment of this disclosure in a direction perpendicular to the substrate when a light-emitting layer is formed in a pixel area defined by a pixel defining layer.

FIG. 12 is a sectional schematic view exemplarily representing a display panel according to another embodiment of this disclosure in a direction perpendicular to the substrate.

FIG. 13 is a sectional schematic view exemplarily representing a display panel according to still another embodiment of this disclosure in a direction perpendicular to the substrate.

### DESCRIPTION OF EMBODIMENTS

The technical solutions in the examples of this disclosure will be described clearly and fully below in conjunction with specific embodiments of this disclosure. Obviously, the embodiments and/or examples described are merely a part of the embodiments and/or examples of this disclosure, rather than all of the embodiments and/or examples. Based on the embodiments and/or examples of this disclosure, all other embodiments and/or examples obtained by those of ordinary skill in the art without performing inventive work belong to the scope protected by this disclosure.

In one aspect of this disclosure, there may be provided a display panel. The display panel may comprise a substrate. A planarization layer may be provided on the substrate. A first electrode may be provided on the planarization layer. A light-emitting layer may be provided on the first electrode. A second electrode may be provided on the light-emitting layer. The display panel comprises an auxiliary electrode, wherein the auxiliary electrode is provided in the planarization layer and is electrically connected to the second electrode.

In another aspect of this disclosure, there may be provided a display apparatus. The display apparatus may comprise a display panel of any one described above.

In still another aspect of this disclosure, there may be provided a method for producing a display panel, comprising the steps of: forming a planarization layer on a substrate, forming a first electrode on the planarization layer; forming a light-emitting layer on the first electrode; and forming a second electrode on the light-emitting layer; wherein an auxiliary electrode is formed in the planarization layer and the auxiliary electrode is electrically connected to the second electrode.

In this disclosure, the term “layer” and the term “film” may be interchangeably used, unless specifically indicated. In the description below, illustrations are made by exemplifying a display panel comprising a thin-film transistor. However, this disclosure is not limited thereto. As used in this disclosure, “about” means to be within an error range of measurement, for example within ±10%, within ±5%, or within ±1% of a defined numeric value. Terms “first”, “second”, “third”, “fourth”, “fifth”, and the like are for the purpose of description only, and cannot be understood as indicating or suggesting relative importance or implying the number of technical features indicated. Thereby, a characteristic defined by “first”, “second”, “third”, “fourth”, “fifth”, and the like may expressly or impliedly comprises one or more characteristics. In this disclosure, “on the surface” in terms “formed on the surface” or “coated on the surface” may comprise “on the whole surface” or “on a part of the surface”.

In the description below, an anode as a first electrode and a cathode as a second electrode are exemplified sometimes. However, this disclosure is not limited thereto. For example, a first electrode may be used as a cathode, and a second electrode may be used as an anode.

With respect to the problem mentioned in the section of background art, in order to improve the display uniformity, it is proposed to use an auxiliary electrode such as an auxiliary cathode connected to a transparent electrode so as to achieve the aim at reducing the resistance of the transparent electrode. For example, the aim at reducing the resistance of a transparent cathode may be achieved by providing an auxiliary cathode in a pixel defining layer. However, since the distance between anodes of pixels is relatively small, there may be no sufficient space to produce an auxiliary cathode. Therefore, the reduction of the resistance of the transparent cathode by using the auxiliary cathode has a limited extent.

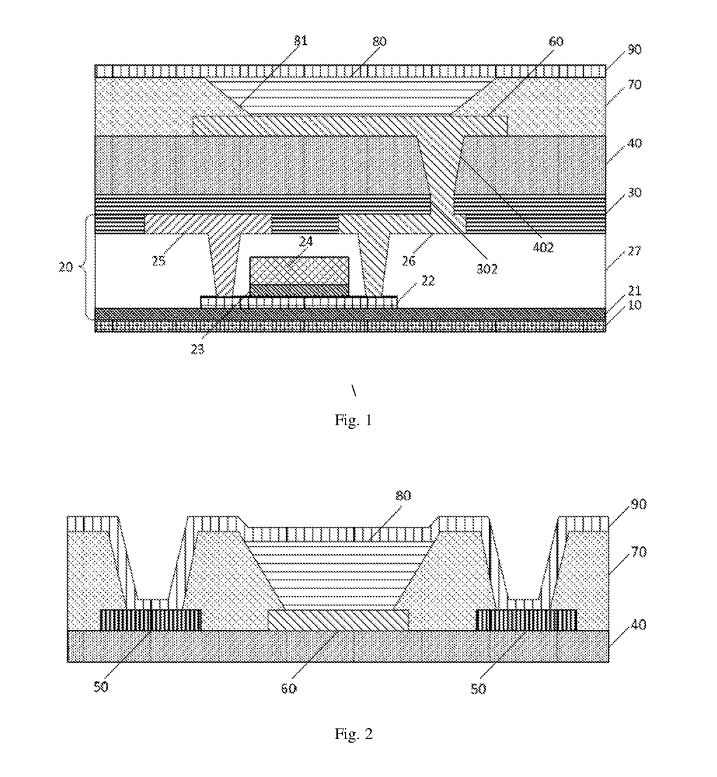

FIG. 1 is a sectional schematic view exemplarily representing a display panel in a direction perpendicular to the substrate.

As shown in FIG. 1, a display panel according to one embodiment may comprise a substrate 10, a thin-film transistor 20 on the substrate 10, a passivation layer 30 on the thin-film transistor 20, a planarization layer 40 on the passivation layer 30, a first electrode 60 and a pixel defining layer 70 on the planarization layer 40, a light-emitting layer 80 on the first electrode 60, and a second electrode 90 on the pixel defining layer 70 and the light-emitting layer 80. As shown in FIG. 1, the thin-film transistor 20 may comprise a buffering layer 21 on the substrate 10, an active layer 22 on the buffering layer 21, a gate electrode insulating layer 23 on the active layer 22, a gate electrode 24 on the gate electrode insulating layer 23, a source electrode 25 and a drain electrode 26 electrically connected to and provided on the active layer 22, and an interlayered dielectric layer 27 for separating the source electrode 25, the drain electrode 26, and the gate electrode 24. The first electrode 60 is electrically connected to the drain electrode 26 of the thin-film transistor 20 via a through hole 302 formed in the passivation layer 30 and a through hole 402 formed in the planarization layer 40. The pixel defining layer 70 defines a pixel area 81, and the light-emitting layer 80 is formed in the pixel area 81.

In the structure as shown in FIG. 1, the second electrode 90 may be specifically implemented as a transparent electrode. The transparent electrode has a relatively high requirement for the transmittance of light, so that the thickness of the transparent electrode should be as thin as possible. However, the thinner the film layer of the transparent electrode is, the higher the resistance thereof is. An excessively high resistance leads to the occurrence of IR drop over the transparent electrode, which influences the display uniformity of the entire surface. This case is particularly notable in a large-size panel. Therefore, it is desirable to use an auxiliary electrode such as an auxiliary cathode connected to a transparent electrode such as a transparent cathode so as to achieve the aim at reducing the resistance of the transparent electrode.

FIG. 2 is a sectional schematic view exemplarily representing another display panel in a direction perpendicular to the substrate.

As shown in FIG. 2, a display panel may comprise a planarization layer 40, a pixel defining layer 70, and a second electrode 90 such as a cathode. A light-emitting layer 80 is formed in the pixel defining layer 70. The cathode covers the pixel defining layer 70 and is connected to the light-emitting layer 80. A first electrode 60 such as an anode is provided between the planarization layer 40 and the light-emitting layer 80 and is connected to the light-emitting layer 80. An auxiliary electrode 50 such as an auxiliary cathode is provided in the pixel defining layer 70. A second electrode 90 such as a cathode is electrically connected to the auxiliary cathode 50.

Similarly, the aim at reducing the resistance of a transparent cathode may be achieved by providing an auxiliary cathode in a pixel defining layer 70. However, since the distance between anodes of pixels is relatively small, there is no sufficient space to produce an auxiliary cathode. Therefore, the reduction of the resistance of the transparent cathode by this auxiliary cathode has a limited extent.

With respect to the problems of the display panels as shown in FIG. 1 and FIG. 2 described above, the inventor of this disclosure has proposed a further improved solution. FIG. 3 is a sectional schematic view exemplarily representing a display panel according to one embodiment of this disclosure in a direction perpendicular to the substrate.

As shown in FIG. 3, a display panel according to this embodiment of this disclosure may comprise a substrate 10, a thin-film transistor 20 on the substrate 10, a passivation layer 30 on the thin-film transistor 20, a planarization layer 40 on the passivation layer 30, a first electrode 60 and a pixel defining layer 70 on the planarization layer 40, a light-emitting layer 80 on the first electrode 60, and a second electrode 90 on the pixel defining layer 70 and the light-emitting layer 80. The thin-film transistor 20 may comprise a buffering layer 21 on the substrate 10, an active layer 22 on the buffering layer 21, a gate electrode insulating layer 23 on the active layer 22, a gate electrode 24 on the gate electrode insulating layer 23, a source electrode 25 and a drain electrode 26 electrically connected to and provided on the active layer 22, and an interlayered dielectric layer 27 for separating the source electrode 25, the drain electrode 26, and the gate electrode 24. The first electrode 60 is electrically connected to the drain electrode 26 of the thin-film transistor 20 via a through hole 302 formed in the passivation layer 30 and a through hole 402 formed in the planarization layer 40. As shown in FIG. 3, the display panel further comprises an auxiliary electrode 50, wherein the auxiliary electrode 50 is provided in the planarization layer 40 and is electrically connected to the second electrode 90. The pixel defining layer 70 defines a pixel area 81, and the light-emitting layer 80 is formed in the pixel area 81.

Thus, by providing the auxiliary electrode 50 being in the planarization layer 40 and electrically connected to the second electrode 90, the area of the auxiliary electrode 50 may be considerably large so as to significantly reduce the resistance of the second electrode 90.

According to another embodiment of this disclosure, the pixel defining layer 70 may be provided on the planarization layer 40 and defines the pixel area 81, and the light-emitting layer 80 is formed in the pixel area 81, wherein the auxiliary electrode 50 is electrically connected to the second electrode 90 via a hole located in the pixel defining layer 70 and the planarization layer 40.

According to another embodiment of this disclosure, the planarization layer 40 may comprise a first planarization sublayer 42 and a second planarization sublayer 44. As shown in FIG. 3, the first planarization sublayer 42 is provided on the substrate 10, wherein the auxiliary electrode 50 is provided on the first planarization sublayer 42 and the second planarization sublayer 44 covers the auxiliary electrode 50 and the first planarization sublayer 42.

According to another embodiment of this disclosure, the pixel defining layer 70 may be provided on the planarization layer 40 and defines the pixel area 81, and the light-emitting layer 80 is formed in the pixel area 81, wherein the auxiliary electrode 50 is electrically connected to the second electrode 90 via a through hole 704 (i.e. a second through hole 704) penetrating the pixel defining layer 70 and a through hole 444 (i.e. a first through hole 444) penetrating the second planarization sublayer 44.

According to another embodiment of this disclosure, the thickness of the first planarization sublayer 42 may be about 0.5 μm to about 1.5 μm, and the thickness of the second planarization sublayer 44 may be about 0.5 μm to about 1.5 μm.

According to another embodiment of this disclosure, the second planarization sublayer 44 may comprise a part 44A covering the auxiliary electrode 50 and a part 44B covering and contacting the first planarization sublayer 42. The thickness of the part 44B covering and contacting the first planarization sublayer 42 is equal to the sum of the thickness of the part 44A covering the auxiliary electrode 50 and the thickness of the auxiliary electrode 50.

According to another embodiment of this disclosure, the ratio D1/(D2+D3) of the thickness D1 of the auxiliary electrode 50 to the sum of the thickness D2 of the first planarization sublayer 42 and the thickness D3 of the part 44B covering and contacting the first planarization sublayer 42 may be about 1:10 to about 1:3, for example about 1:9 to about 1:3.5, for example about 1:8 to about 1:4, or for example about 1:7 to about 1:4. By this embodiment, the area of the auxiliary electrode 50 may be considerably large so as to significantly reduce the resistance of the second electrode 90, in the case where the function of the planarization layer 40 comprising the first planarization sublayer 42 and the second planarization sublayer 44 is ensured.

According to another embodiment of this disclosure, the thickness of the auxiliary electrode 50 may be about 300 nm to about 750 nm, for example about 350 nm to about 700 nm, or for example about 400 nm to about 650 nm.

According to another embodiment of this disclosure, the sum of the thickness of the first planarization sublayer 42 and the thickness of the part 44B covering and contacting the first planarization sublayer 42 may be about 1 μm to about 3 μm, for example about 1.2 μm to about 2.5 μm.

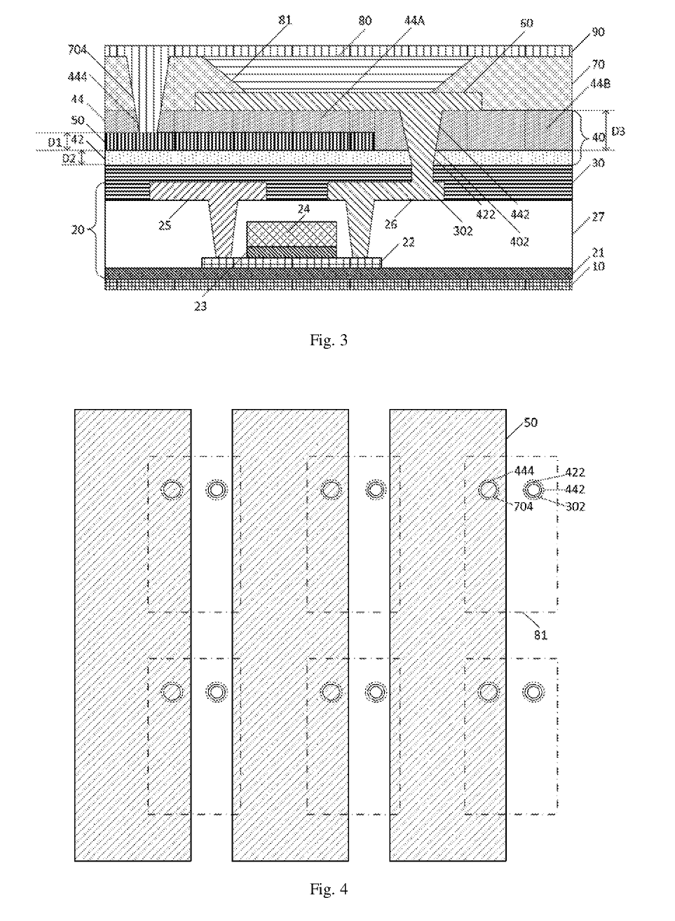

FIG. 4 is a schematic plan view exemplarily representing an auxiliary electrode 50 of a display panel according to another embodiment of this disclosure.

As shown in FIG. 4, an auxiliary electrode 50 may be electrically connected to a second electrode 90 via a second through hole 704 and a first through hole 444. A first electrode 60 is electrically connected to a drain electrode 26 of a thin-film transistor 20 via a through hole 302 (i.e. a fifth through hole 302) formed in a passivation layer 30, a through hole 422 (i.e. a third through hole 422) formed in a first planarization sublayer 42, and a through hole 442 formed in a second planarization sublayer 44 (i.e. a fourth through hole 442). A pixel defining layer 70 is used for defining a plurality of pixel areas 81. A through hole 402 of a planarization layer 40 comprises the third through hole 422 in the first planarization sublayer 42 and the fourth through hole 442 in the second planarization sublayer 44. Remaining parts in FIG. 4 are the same as or similar to those in FIG. 3.

The auxiliary electrode 50 may be a mesh electrode.

According to another embodiment of this disclosure, since the through hole 402 for electrically connecting the first electrode 60 to the drain electrode 26 is formed and the auxiliary electrode 50 electrically connected to the second electrode 90 is formed in the planarization layer 40, the auxiliary electrode 50 may be formed in an area away from an area for forming the through hole 402 so as to electrically separate the auxiliary electrode 50 from a conductive material in the through hole 402.

According to another embodiment of this disclosure, the ratio of the area of the auxiliary electrode 50 in a direction parallel to the substrate to the area of the planarization layer 40 or the first planarization sublayer 42 or the second planarization sublayer 44 in a direction parallel to the substrate may be about 1:1.2 to about 1:5, or about 1:1.3 to about 1:4, or about 1:1.3 to about 1:3, or about 1:1.5 to about 1:2. Since the area of the first planarization sublayer 42 or the second planarization sublayer 44 in a direction parallel to the substrate is equal to the area of the substrate 10, the area of the auxiliary electrode 50 may be considerably large so as to significantly reduce the resistance of the second electrode 90.

According to another embodiment of this disclosure, the auxiliary electrode 50 may comprise a conductive metal layer. The conductive metal layer may comprise a conductive metal selected from the group consisting of copper, silver, aluminum, alloys of any two or three of them, and mixtures thereof.

According to another embodiment of this disclosure, the auxiliary electrode 50 may have a multilayer structure comprising a first protective conductive layer, a conductive metal layer, and a second protective conductive layer. The conductive metal layer is located between the first protective conductive layer and the second protective conductive layer. The multilayer structure may comprise a three-layer structure of first protective conductive layer/conductive metal layer/second protective conductive layer. The thicknesses of the first protective conductive layer and the second protective conductive layer may be each independently about 10 to about 100 nm, for example about 20 to about 90 nm, or for example about 30 to about 80 nm. The thickness of the conductive metal layer may be about 300 to about 500 nm, for example about 350 to about 450 nm.

An auxiliary electrode 50 material and a first electrode material may be selected such that the etching ratio therebetween is as large as possible. For example, MoNb/Cu/MoNb is selected as the auxiliary electrode 50, and AlNd or Al is selected as the first electrode 60 so as to ensure that an etching liquid for etching AlNd or Al will not destroy the exposed auxiliary electrode 50 MoNb/Cu/MoNb when the first electrode 60 is etched.

According to another embodiment of this disclosure, the materials used by the first electrode 60 and the drain electrode 26 of the thin-film transistor 20 may be the same or different.

According to another embodiment of this disclosure, the first electrode 60 may comprise AlNd or Al. The auxiliary electrode 50 may have a multilayer structure comprising a first protective conductive layer, a conductive metal layer, and a second protective conductive layer. The conductive metal layer is located between the first protective conductive layer and the second protective conductive layer. The first protective conductive layer and the second protect conductive may comprise MoNb. The conductive metal layer may be an aluminum layer, a copper layer, or a silver layer.

According to another embodiment of this disclosure, the first electrode 60 may be an anode and the second electrode 90 may be a cathode.

According to another embodiment of this disclosure, the thickness of the cathode may be about 50 nm to about 200 nm, for example about 60 nm to about 180 nm, or for example about 80 nm to about 160 nm.

According to another embodiment of this disclosure, the cathode may comprise IZO, ITO, AZO, or Ag nanowires.

In the display panel as shown in FIG. 1, the material of the planarization layer 40 is poly(methyl methacrylate) and the thickness is 4 μm; the anode is AlNd and the thickness is 300 nm; the material of the pixel defining layer 70 is polyimide and the thickness is 2.5 μm; and the cathode is IZO and the thickness is 80 nm. By connecting metal pads of Mo (600 Angstroms)/AlNd (5000 Angstroms)/Mo (600 Angstroms) to two ends of the cathode, it has been found that the resistance between two metal pads was about 10Ω.

According to an example of this disclosure, in the display panel as shown in FIG. 3, the material of the first planarization sublayer 42 is poly(methyl methacrylate) and the thickness is 2 μm; the auxiliary cathode is a mesh electrode as shown in FIG. 4, which employs a three-layer structure of MoNb/Cu/MoNb, wherein the thicknesses of the two MoNb layers are both 50 nm, the thickness of the Cu layer is 400 nm, and the ratio of the surface area of the auxiliary cathode to the surface area of the first planarization sublayer 42 is 0.75:1; the material of the first planarization sublayer 42 is poly(methyl methacrylate) and the thickness is 2 μm; the anode is AlNd and the thickness is 300 nm; the material of the pixel defining layer 70 is polyimide and the thickness is 2.5 μm; and the cathode is IZO and the thickness is 80 nm. By connecting metal pads of Mo (600 Angstroms)/AlNd (5000 Angstroms)/Mo (600 Angstroms) to two ends of the cathode, it has been found that the resistance between two metal pads was about 4Ω.

Therefore, by providing the auxiliary electrode 50 being in the planarization layer 40 and electrically connected to the second electrode 90, the area of the auxiliary electrode 50 may be considerably large so as to significantly reduce the resistance of the second electrode 90. For example, in a case where metal pads of Mo (600 Angstroms)/AlNd (5000 Angstroms)/Mo (600 Angstroms) were connected to two ends of the cathode, the resistance between two metal pads may be reduced from about 10Ω in absence of the auxiliary electrode 50 to about 4Ω in the presence of the auxiliary electrode 50.

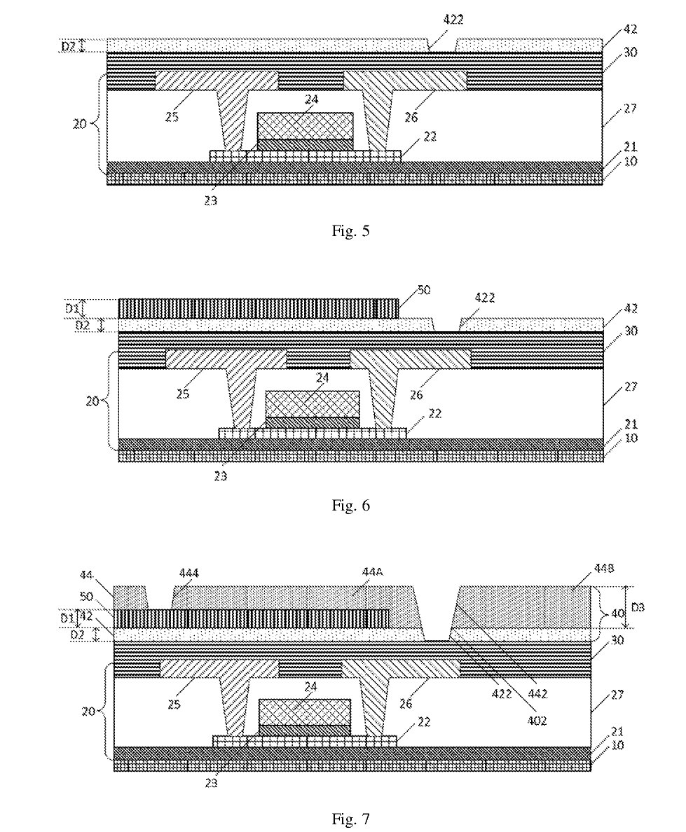

FIG. 5 to FIG. 11 are sectional schematic views exemplarily representing a display panel according to another embodiment of this disclosure in a direction perpendicular to the substrate when a first planarization sublayer 42 is formed on a passivation layer 30, an auxiliary electrode 50 is formed and patterned, a second planarization sublayer 44 is formed, a fifth through hole 302 is formed in the passivation layer 30 to expose a drain electrode 26, a first electrode 60 is formed on the second planarization sublayer 44 and patterned, a pixel defining layer 70 is formed on the second planarization sublayer 44, and a light-emitting layer 80 is formed in a pixel area 81 defined by the pixel defining layer 70, respectively.

According to one embodiment of this disclosure, there may be provided a method for producing a display panel, comprising the steps of:
forming a first planarization sublayer 42 on a substrate 10;
forming an auxiliary electrode 50 on the first planarization sublayer 42;
forming a second planarization sublayer 44 on the first planarization sublayer 42 having the auxiliary electrode formed thereon 50;
forming a first through hole 444, which is in communication with the auxiliary electrode 50, in the second planarization sublayer 44;
forming a first electrode 60 on the second planarization sublayer 44 by using a first electrode material;
forming a pixel defining layer 70, which defines a pixel area 81, on the second planarization sublayer 44;
forming a second through hole 704, which is in communication with the first through hole 444, in the pixel defining layer 70;
forming a light-emitting layer 80 in the pixel area 81; and
forming a second electrode 90 on surfaces of the light-emitting layer 80 and the pixel defining layer 70 by using a second electrode material, wherein the second electrode material fills the first through hole 444 and the second through hole 704, and is electrically connected to the auxiliary electrode 50.

The display panel further comprises a passivation layer 30 located on the substrate 10 and under the first planarization sublayer 42, and a thin-film transistor 20 located on the substrate 10 and under the passivation layer 30, wherein the thin-film transistor 20 has a drain electrode 26, the method further comprises:
forming a third through hole 422 in the first planarization sublayer 42 and above the drain electrode 26;
forming a fourth through hole 442 in the second planarization sublayer 44; and
forming a fifth through hole 302 in the passivation layer 30, wherein the fifth through hole 302 and the fourth through hole 442 are in communication with the third through hole 422;
wherein when forming a first electrode 60 on the second planarization sublayer 44 by using a first electrode material, the first electrode material fills the fourth through hole 442, the third through hole 422, and the fifth through hole 302, and the first electrode is electrically connected to the drain electrode 26 of the thin-film transistor 20.

A sectional schematic view of the display panel in a direction perpendicular to the substrate after the second electrode 90 is formed on the pixel defining layer 70 and the light-emitting layer 80 is shown in FIG. 3. The substrate 10, the thin-film transistor 20 on the substrate 10, and the passivation layer 30 on the thin-film transistor 20 in each of FIG. 5 to FIG. 11 are the same as those in FIG. 3. For the purpose of simplicity, detailed descriptions thereof are not made hereby.

FIG. 5 is a sectional schematic view exemplarily representing a display panel according to another embodiment of this disclosure in a direction perpendicular to the substrate when a first planarization sublayer 42 is formed on a passivation layer 30.

As shown in FIG. 5, the first planarization sublayer 42 is formed on the passivation layer 30 as shown in FIG. 3. The material for forming the first planarization sublayer 42 may be poly(methyl methacrylate), polyimide, and a silicone resin. The thickness of the first planarization sublayer 42 may be about 0.5 μm to about 1.5 μm, for example about 0.6 to about 1.5 μm, or about 0.8 to about 1.2 μm. The forming method may comprise spin coating, then exposing, developing, and etching. After coating, exposing, developing, and etching on the surface of the passivation layer 30, the third through hole 422 is formed in the first planarization sublayer 42 and above the drain electrode 26.

FIG. 6 is a sectional schematic view exemplarily representing a display panel according to another embodiment of this disclosure in a direction perpendicular to the substrate when an auxiliary electrode 50 is formed on a first planarization sublayer 42 and is patterned.

As shown in FIG. 6, the auxiliary electrode 50 is formed on the first planarization sublayer 42 as shown in FIG. 5. An auxiliary electrode 50 material layer may be formed on the surface of the first planarization sublayer 42 by sputtering, and is then formed into a mesh electrode by a patterning process, as shown in FIG. 4. The patterning process may comprise exposing, developing, and etching. The auxiliary electrode 50 may also be formed on the first planarization sublayer 42 in a mesh form by an ink-jet printing process. Since the through hole 422 for electrically connecting the first electrode 60 to the drain electrode 26 is formed in the first planarization sublayer 42 and the auxiliary electrode 50 electrically connected to the second electrode 90 is formed thereon, the auxiliary electrode 50 may be formed in an area away from an area for forming the through hole 422 so as to electrically separate the auxiliary electrode 50 from a conductive material in the through hole 402.

FIG. 7 is a sectional schematic view exemplarily representing a display panel according to another embodiment of this disclosure in a direction perpendicular to the substrate when a second planarization sublayer 44 is formed on a first planarization sublayer 42 and an auxiliary electrode 50.

As shown in FIG. 7, the second planarization sublayer 44 is formed on the first planarization sublayer 42 and the auxiliary electrode 50 as shown in FIG. 6. The material of the second planarization sublayer 44 may be poly(methyl methacrylate), polyimide, and a silicone resin. The thickness of the second planarization sublayer 44 may be about 0.5 μm to about 1.5 μm, for example about 0.6 to about 1.5 μm, or about 0.8 to about 1.2 μm. The forming method may comprise spin coating, then exposing, developing, and etching. After coating, exposing, developing, and etching on the surface of the passivation layer 30, the fourth through hole 442 in communication with the third through hole 422 and the first through hole 444 in communication with the auxiliary electrode 50 are formed in the second planarization sublayer 44.

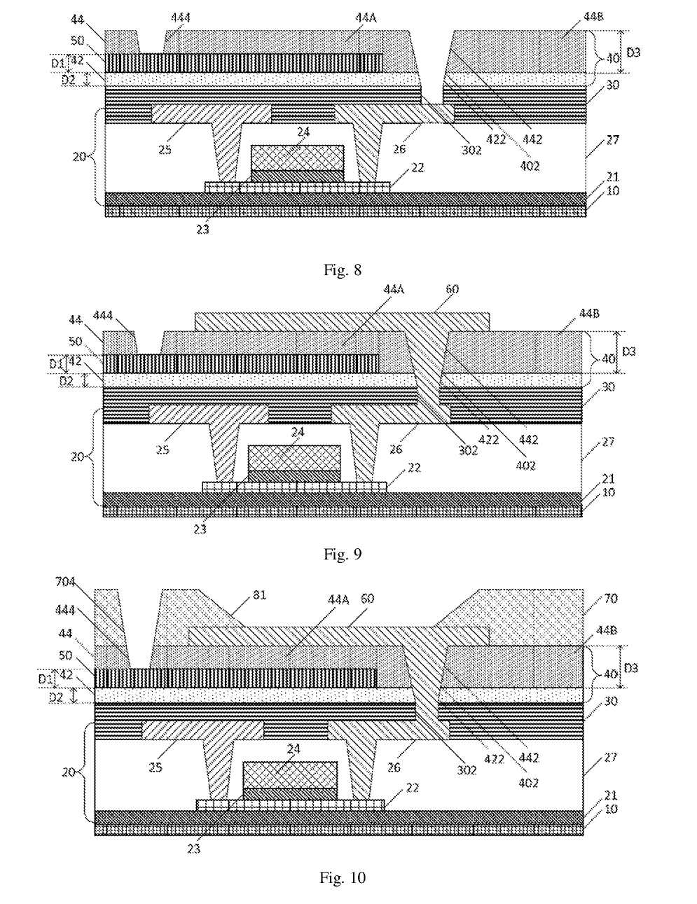

FIG. 8 is a sectional schematic view exemplarily representing a display panel according to another embodiment of this disclosure in a direction perpendicular to the substrate when a fifth through hole 302 is formed in a passivation layer 30 to expose a drain electrode 26.

As shown in FIG. 8, the fifth through hole 302 is formed in the passivation layer 30 by dry etching. The fifth through hole 302, the fourth through hole 442, and the third through hole 422 are in communication so as to expose the drain electrode 26.

FIG. 9 is a sectional schematic view exemplarily representing a display panel according to another embodiment of this disclosure in a direction perpendicular to the substrate when a first electrode 60 is formed on a second planarization sublayer 44 and is patterned.

As shown in FIG. 9, the first electrode 60 is formed on the second planarization sublayer 44 as shown in FIG. 8. A first electrode material layer may be formed on the surface of the second planarization sublayer 44 and in the fifth through hole 302, third through hole 422, and the fourth through hole 442 by sputtering. The first electrode material layer formed on the surface of the second planarization sublayer 44 is then formed into the first electrode 60 by a patterning process. The patterning process may comprise exposing, developing, and etching. The first electrode 60 is electrically connected to the drain electrode 26 via the first electrode material in the fifth through hole 302, third through hole 422, and the fourth through hole 442.

FIG. 10 is a sectional schematic view exemplarily representing a display panel according to another embodiment of this disclosure in a direction perpendicular to the substrate when a pixel defining layer 70 is formed on a second planarization sublayer 44.

As shown in FIG. 10, the pixel defining layer 70 is formed on the second planarization sublayer 44 as shown in FIG. 9 to define the pixel area 81, and the light-emitting layer 80 is formed in the pixel area 81. The material for forming the pixel defining layer 70 may be poly(methyl methacrylate), polyimide, and a silicone resin. The thickness of the pixel defining layer 70 may be about 1 μm to about 5 μm, for example about 1 μm to about 3 μm, or for example about 2 μm to about 3 μm. The forming method may comprise spin coating, then exposing, developing, and etching. After coating, exposing, then developing, and etching on the surface of the second planarization sublayer 44, the second through hole 704 is formed in the pixel defining layer 70 to be in communication with the first through hole 444 so as to expose the auxiliary electrode 50.

FIG. 11 is a sectional schematic view exemplarily representing a display panel according to another embodiment of this disclosure in a direction perpendicular to the substrate when a light-emitting layer 80 is formed in a pixel area 81 defined by a pixel defining layer 70.

As shown in FIG. 11, the light-emitting layer 80 is formed in the pixel area 81 defined by the pixel defining layer 70. The light-emitting layer 80 may be formed from an organic light-emitting material by an ink-jet printing process.

Then, the second electrode 90 is formed from a second electrode material on the whole surface of the pixel defining layer 70 and the surface of the light-emitting layer 80 as shown in FIG. 11. The second electrode material fills the first through hole 444 and second through hole 704, which expose the auxiliary electrode 50. The thickness of the second electrode 90 may be about 50 nm to about 200 nm, for example about 60 nm to about 180 nm, or for example about 80 nm to about 160 nm. The display panel after the second electrode 90 is formed is as shown in FIG. 3.

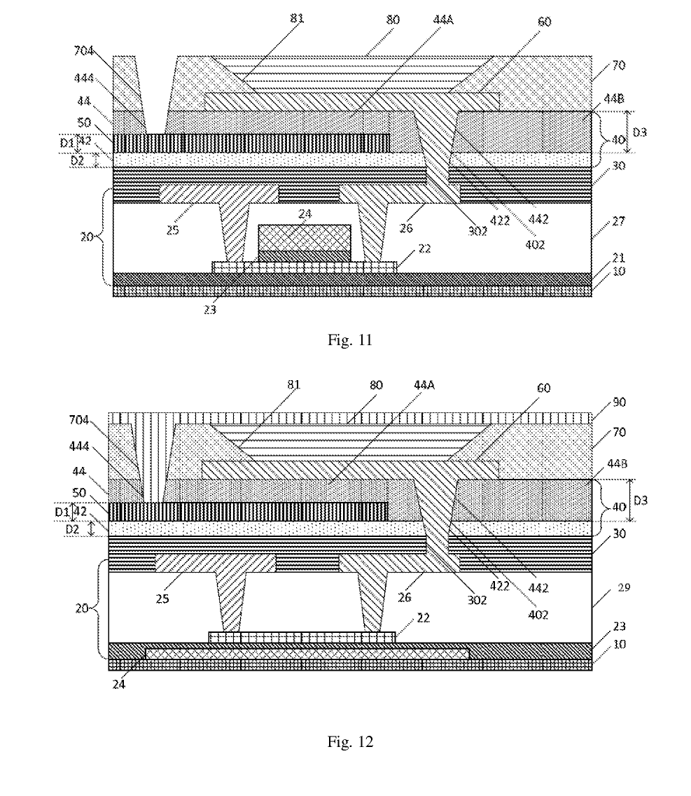

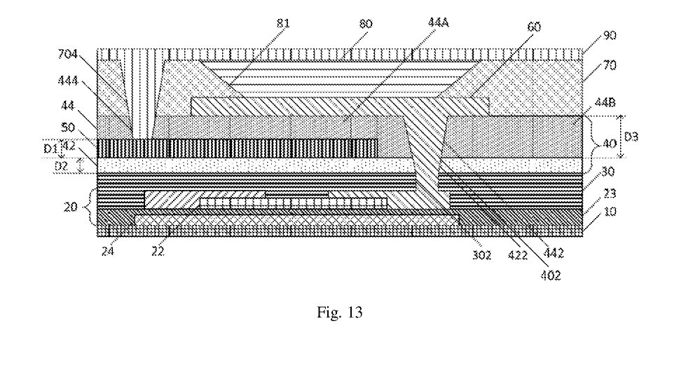

Illustrations are made by exemplifying a display panel comprising a top-gate thin-film transistor 20 in FIG. 3 and FIGS. 5-11. However, this disclosure is not limited thereto. For example, the display panel of this disclosure may employ a configuration as shown in FIG. 12 or FIG. 13.

FIG. 12 is a sectional schematic view exemplarily representing a display panel according to another embodiment of this disclosure in a direction perpendicular to the substrate.

FIG. 12 shows a display panel comprising a bottom-gate thin-film transistor 20 having an etching barrier layer. As shown in FIG. 12, a gate electrode 24 is between an active layer 22 and a substrate 10, and the bottom-gate thin-film transistor 20 has an etching barrier layer 29. The etching barrier layer 29 covers the active layer 22 and a gate electrode insulating layer 23 which is not covered by the active layer 22, and separates a source electrode 25 and a drain electrode 26. The passivation layer 30 and parts above the passivation layer 30 of the display panel as shown in FIG. 12 are the same as the passivation layer 30 and parts above the passivation layer 30 as shown in FIG. 3.

FIG. 13 is a sectional schematic view exemplarily representing a display panel according to still another embodiment of this disclosure in a direction perpendicular to the substrate.

FIG. 13 shows a display panel comprising a back-channel bottom-gate thin-film transistor 20. As shown in FIG. 13, a gate electrode 24 is between an active layer 22 and a substrate 10. The passivation layer 30 and parts above the passivation layer 30 of the display panel as shown in FIG. 13 are the same as the passivation layer 30 and parts above the passivation layer 30 as shown in FIG. 3.

According to this disclosure, there may be provided a display panel, a display apparatus comprising a display panel, and a method for producing a display panel, wherein the display panel comprises an auxiliary electrode, and the auxiliary electrode is provided in the planarization layer and is electrically connected to the second electrode. The area of the auxiliary electrode may be considerably large so as to significantly reduce the resistance of the second electrode.

Obviously, various modifications and variations may be made to the examples of this disclosure by the person skilled in the art without deviating from the spirit and the scope of this disclosure. Thus, if these modifications and variations of this disclosure are within the scope of the claims of this disclosure and equivalent techniques thereof, this disclosure also intends to encompass these modifications and variations.

What is claimed is:

1. A display panel, comprising:
a substrate;
a planarization layer on the substrate;
a first electrode on the planarization layer;
a light-emitting layer on the first electrode;
a second electrode on the light-emitting layer; and
an auxiliary electrode, which is in the planarization layer and electrically connected to the second electrode.

2. The display panel according to claim 1, further comprising: a pixel defining layer, which is on the planarization layer and defines a pixel area, wherein the light-emitting layer is in the pixel area, and
wherein the auxiliary electrode is electrically connected to the second electrode via a hole located in the pixel defining layer and the planarization layer.

3. The display panel according to claim 1, wherein the planarization layer comprises:
a first planarization sublayer, and
a second planarization sublayer,
wherein the first planarization sublayer is on the substrate, the auxiliary electrode is on the first planarization sublayer, and the second planarization sublayer covers the auxiliary electrode and the first planarization sublayer.

4. The display panel according to claim 3, further comprising: a pixel defining layer, which is on the second planarization sublayer and defines a pixel area, wherein the light-emitting layer is in the pixel area, and
wherein the auxiliary electrode is electrically connected to the second electrode via a through hole penetrating the pixel defining layer and the second planarization sublayer.

5. The display panel according to claim 3, wherein a thickness of the first planarization sublayer is 0.5 μm to 1.5 μm, and a thickness of the second planarization sublayer is 0.5 μm to 1.5 μm.

6. The display panel according to claim 3, wherein the second planarization sublayer comprises a part covering the auxiliary electrode and a part covering and contacting the first planarization sublayer, wherein a thickness of the part covering and contacting the first planarization sublayer is equal to a sum of a thickness of the part covering the auxiliary electrode and a thickness of the auxiliary electrode.

7. The display panel according to claim 6, wherein a ratio D1/(D2+D3) of a thickness D1 of the auxiliary electrode to a sum of a thickness D2 of the first planarization sublayer and a thickness D3 of the part covering and contacting the first planarization sublayer is 1:10 to 1:3.

8. The display panel according to claim 6, wherein a thickness of the auxiliary electrode is 300 nm to 750 nm; and a sum of a thickness of the first planarization sublayer and a thickness of the part covering and contacting the first planarization sublayer is 1 μm to 3 μm.

9. The display panel according to claim 1, wherein a ratio of an area of the auxiliary electrode in a direction parallel to the substrate to an area of the planarization layer in a direction parallel to the substrate is 1:1.2 to 1:5.

10. The display panel according to claim 1, wherein the auxiliary electrode is a mesh electrode.

11. The display panel according to claim 1, wherein the auxiliary electrode has a multilayer structure comprising a first protective conductive layer, a conductive metal layer, and a second protective conductive layer, wherein the conductive metal layer is located between the first protective conductive layer and the second protective conductive layer, thicknesses of the first protective conductive layer and the second protective conductive layer are each independently 10 to 100 nm, and a thickness of the conductive metal layer is 300 to 500 nm.

12. The display panel according to claim 11, wherein the first electrode comprises AlNd or Al, the conductive metal layer comprises Cu, and the first protective conductive layer and the second protective conductive layer comprise MoNb.

13. The display panel according to claim 1, wherein the first electrode is an anode, and the second electrode is a cathode.

14. A display apparatus, comprising the display panel according to claim 1.

15. A method for producing the display panel according to claim 1, comprising the steps of:
forming a planarization layer on a substrate,
forming a first electrode on the planarization layer;
forming a light-emitting layer on the first electrode; and
forming a second electrode on the light-emitting layer;
wherein an auxiliary electrode is formed in the planarization layer and the auxiliary electrode is electrically connected to the second electrode.

16. The method according to claim 15, comprising the steps of:
forming a first planarization sublayer on a substrate;
forming an auxiliary electrode on the first planarization sublayer;
forming a second planarization sublayer on the first planarization sublayer having the auxiliary electrode formed thereon;
forming a first through hole, which is in communication with the auxiliary electrode, in the second planarization sublayer;
forming a first electrode on the second planarization sublayer by using a first electrode material;
forming a pixel defining layer, which defines a pixel area, on the second planarization sublayer;
forming a second through hole, which is in communication with the first through hole, in the pixel defining layer;
forming a light-emitting layer in the pixel area; and
forming a second electrode on surfaces of the light-emitting layer and the pixel defining layer by using a second electrode material, wherein the second electrode material fills the first through hole and the second through hole, and is electrically connected to the auxiliary electrode.

17. The method according to claim 16, wherein the display panel further comprises a passivation layer located on the substrate and under the first planarization sublayer, and a thin-film transistor located on the substrate and under the passivation layer, wherein the thin-film transistor has a drain electrode,
and the method further comprises:
forming a third through hole in the first planarization sublayer and above the drain electrode;
forming a fourth through hole in the second planarization sublayer; and
forming a fifth through hole in the passivation layer, wherein the fifth through hole and the fourth through hole are in communication with the third through hole;
wherein when forming a first electrode on the second planarization sublayer by using a first electrode material, the first electrode material fills the fourth through hole, the third through hole, and the fifth through hole, and electrically connects the first electrode to the drain electrode of the thin-film transistor.
